(19) United States
(12) Patent Application Publication
(10) Pub. No.: US 2026/0013332 A1
(43) Pub. Date: Jan. 8, 2026

(54) DISPLAY DEVICE

(71) Applicant: Samsung Display Co., Ltd., Yongin-si (KR)

(72) Inventors: Ki Nyeng KANG, Yongin-si (KR); Sug Woo JUNG, Yongin-si (KR); Young Cheol JEONG, Yongin-si (KR)

(21) Appl. No.: 19/212,263

(22) Filed: May 19, 2025

(30) Foreign Application Priority Data
Jul. 8, 2024 (KR) 10-2024-0089769

(51) Int. Cl. H10K 59/122

(52) U.S. Cl. CPC H10K 59/122

(57) ABSTRACT

Provided is a display device including a substrate, an insulating layer above the substrate, and defining a trench, a first electrode above the insulating layer and adjacent to the trench in plan view, a light-providing layer above the first electrode, and a second electrode above the light-providing layer.

### CROSS-REFERENCE TO RELATED APPLICATION

The present application claims priority to, and the benefit of, Korean Patent Application No. 10-2024-0089769, filed on Jul. 8, 2024, in the Korean Intellectual Property Office, the entire disclosure of which is incorporated herein by reference.

### BACKGROUND

### 1. Field

The present disclosure relates to a display device that can reduce or prevent color mixing between adjacent pixels by reducing or minimizing lateral leakage current between the adjacent pixels.

### 2. Description of the Related Art

A head-mounted display is an image display device that is worn on a user's head in the form of glasses or a helmet, and focuses at a relatively short distance from the user's eyes. The head-mounted display can implement virtual reality (VR) or augmented reality (AR).

The head-mounted display magnifies and displays an image, which is displayed by a small display device, using a plurality of lenses. Therefore, a display device applied to the head-mounted display is required to provide a high-resolution image, for example, an image having a resolution of about 3000 pixels per inch (PPI) or higher. To this end, an organic light-emitting diode on silicon (OLEDoS), which is a small high-resolution organic light-emitting display device, is used as the display device applied to the head-mounted display. The OLEDoS is a device that displays an image by placing an organic light-emitting diode (OLED) on a semiconductor wafer substrate on which a complementary metal oxide semiconductor (CMOS) is located.

### SUMMARY

Aspects of the present disclosure provide a display device which can reduce or prevent color mixing between adjacent pixels by reducing or minimizing lateral leakage current between the adjacent pixels.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including a substrate, an insulating layer above the substrate, and defining a trench, a first electrode above the insulating layer and adjacent to the trench in plan view, a light-providing layer above the first electrode, and a second electrode above the light-providing layer.

The display device may further include a bank above the insulating layer, wherein the trench is between the first electrode and the bank in plan view.

The bank may protrude from the insulating layer along a first direction, wherein the trench is recessed from an upper surface of the insulating layer along a direction that is opposite to the first direction.

The trench may surround the first electrode in plan view.

The bank may surround the trench and the first electrode in plan view.

The bank may include a first sub-bank above the insulating layer, and a second sub-bank above the first sub-bank.

A width of the first sub-bank may be greater than a width of the second sub-bank.

The bank may further include a third sub-bank above the second sub-bank.

A width of the second sub-bank may be less than a width of the third sub-bank.

The second sub-bank may have a width that gradually increases along a direction from the first sub-bank toward the third sub-bank.

A thickness of the insulating layer in an area overlapping the bank may be greater than a thickness of the insulating layer in an area overlapping the trench, and may be less than a thickness of the insulating layer in an area overlapping the first electrode.

A thickness of the insulating layer in an area overlapping the first electrode may be greater than a thickness of the insulating layer in an area overlapping the trench, and may be less than a thickness of the insulating layer in an area overlapping the bank.

A thickness of the insulating layer in an area overlapping the first electrode may be greater than a thickness of the insulating layer in an area overlapping the trench, and may be substantially equal to a thickness of the insulating layer in an area overlapping the bank.

The display device may further include a pixel-defining layer between the first electrode and the light-providing layer.

Edges of the pixel-defining layer may surround the first electrode in plan view.

The trench may surround the pixel-defining layer and the first electrode in plan view.

At least a portion of the light-providing layer may be above the bank and in the trench.

A portion of the light-providing layer above the bank, a portion of the light-providing layer in the trench, and a portion of the light-providing layer above the first electrode may be separated from each other.

A taper angle of the first electrode may be less than about 60 degrees.

The display device may further include an encapsulation layer above the second electrode.

The display device may further include a color filter above the encapsulation layer.

According to an aspect of the present disclosure, there is provided an electronic device including a display device including a substrate, an insulating layer above the substrate, and defining a trench, a first electrode above the insulating layer and adjacent to the trench in plan view, a light-providing layer above the first electrode, and a second electrode above the light-providing layer.

The electronic device may include a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, a head-mounted display (HMD), a virtual reality (VR) device, or an augmented reality (AR) device.

A display device according to the present disclosure can reduce or prevent color mixing between adjacent pixels by reducing or minimizing lateral leakage current between the adjacent pixels. Therefore, the image quality of the display device can be improved.

The aspects according to one or more embodiments of the present disclosure are not limited to those mentioned above and more various aspects are included in the following description of the present disclosure.

### BRIEF DESCRIPTION OF THE DRAWINGS

These and/or other aspects will become apparent and more readily appreciated from the following description of one or more embodiments, taken in conjunction with the accompanying drawings in which:

FIG. 1 is a schematic plan view of a display device according to one or more embodiments;

FIG. 2 is a plan view illustrating the display device according to one or more embodiments;

FIG. 3 is a cross-sectional view taken along the line I-I′ of FIG. 2;

FIG. 4 is an enlarged view of area A1 of FIG. 3;

FIG. 5 is a diagram obtained by removing a light-providing layer, a common electrode, a first encapsulating inorganic layer, and an encapsulating organic layer from FIG. 4;

FIG. 6 is a cross-sectional view of one or more embodiments taken along the line I-I′ of FIG. 2;

FIG. 7 is an enlarged view of area A2 of FIG. 6;

FIG. 8 is a diagram obtained by removing a light-providing layer, a common electrode, a first encapsulating inorganic layer, and an encapsulating organic layer from FIG. 7;

FIG. 9 is a cross-sectional view of one or more embodiments taken along the line I-I′ of FIG. 2;

FIG. 10 is an enlarged view of area A3 of FIG. 9;

FIG. 11 is a diagram obtained by removing a light-providing layer, a common electrode, a first encapsulating inorganic layer, and an encapsulating organic layer from FIG. 10;

FIG. 12 is a cross-sectional view of one or more embodiments taken along the line I-I′ of FIG. 2;

FIG. 13 is an enlarged view of area A4 of FIG. 12;

FIG. 14 is a diagram obtained by removing a light-providing layer, a common electrode, a first encapsulating inorganic layer, and an encapsulating organic layer from FIG. 13;

FIG. 15 is a cross-sectional view of one or more embodiments taken along the line I-I′ of FIG. 2;

FIG. 16 is an enlarged view of one or more embodiments of area A1 of FIG. 3;

FIG. 17 is a cross-sectional view of one or more embodiments taken along the line I-I′ of FIG. 2;

FIG. 18 is a diagram for explaining the breaking of a light-providing layer by a bank and trenches; and

FIG. 19 is a perspective view of a head-mounted display device according to one or more embodiments.

FIG. 20 is a block diagram of an electronic device according to one embodiment.

FIGS. 21, 22 and 23 are schematic diagrams of electronic devices according to various embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof.

Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure.

The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

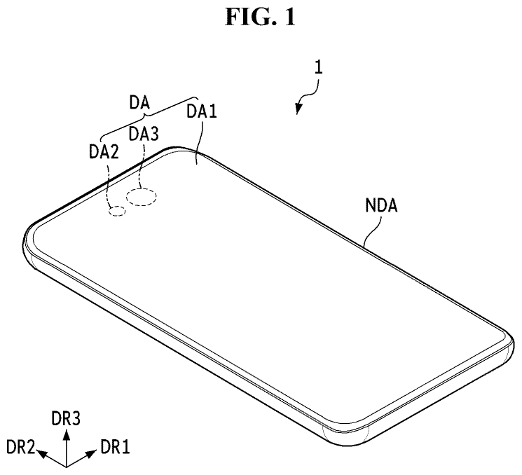

FIG. 1 is a schematic plan view of a display device according to one or more embodiments.

Referring to FIG. 1, an electronic device 1 displays moving images or still images. The electronic device 1 may refer to any electronic device that provides a display screen. Examples of the electronic device 1 may include a television, a notebook computer, a monitor, a billboard, an Internet of things (IoT) device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game console, a digital camera and a camcorder, all of which provide a display screen. The electronic device 1 may also be a portable electronic device, such as an ultra-mobile PC (UMPC), or may be a laptop computer, a virtual reality (VR) device, an augmented reality (AR) device, and/or a head-mounted display device (HMD) (e.g., for implementing virtual reality and/or augmented reality).

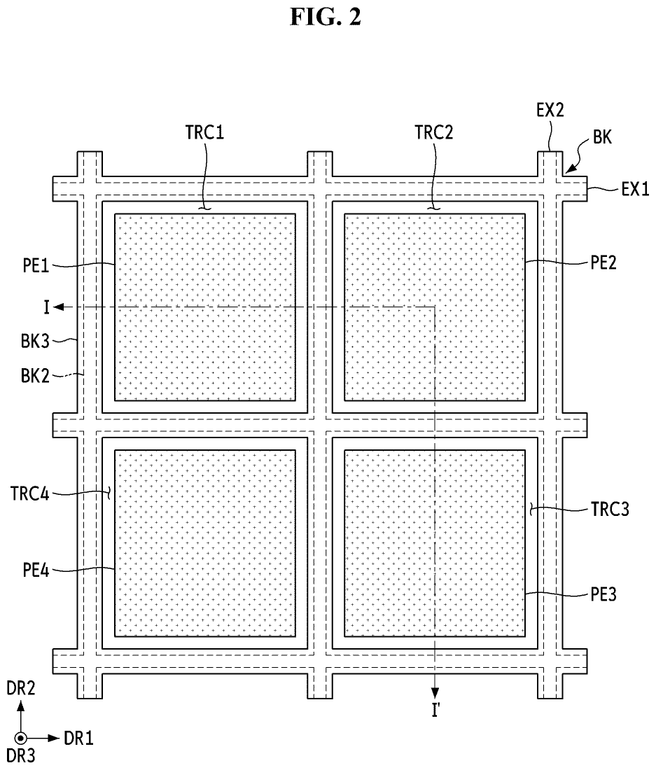

The electronic device 1 may include a display device (see FIG. 2) that provides a display screen. Examples of the display device may include an inorganic light-emitting diode display device, an organic light-emitting display device, a quantum dot light-emitting display device, a plasma display panel, and a field emission display device. A case where an organic light-emitting diode display device is applied as an example of the display device will be described below, but the present disclosure is not limited to this case, and other display devices can also be applied as long as the same technical spirit is applicable.

The shape of the electronic device 1 can be variously modified. For example, the electronic device 1 may have various shapes, such as a horizontally long rectangle, a vertically long rectangle, a square, a quadrilateral with rounded corners (vertices), other polygons, and a circle. The shape of a display area DA of the electronic device 1 may also be similar to the overall shape of the electronic device 1. In FIG. 1, the electronic device 1 is shaped like a rectangle that is long in a second direction DR2.

The electronic device 1 may include the display area DA and a non-display area NDA. The display area DA may be an area where a screen is displayed, and the non-display area NDA may be an area where no screen is displayed. The display area DA may also be referred to as an active area, and the non-display area NDA may also be referred to as an inactive area. The display area DA may generally occupy a center of the electronic device 1.

The display area DA may include a first display area DA1, a second display area DA2, and a third display area DA3. The second display area DA2 and the third display area DA3 may be areas where components for adding various functions to the electronic device 1 are arranged. The second display area DA2 and the third display area DA3 may be component areas.

FIG. 2 is a plan view illustrating the display device according to one or more embodiments.

As illustrated in FIG. 2, the display device may include a first pixel electrode PE1, a second pixel electrode PE2, a third pixel electrode PE3, a fourth pixel electrode PE4, a bank BK, and trenches TRC1 through TRC4.

The first pixel electrode PE1, the second pixel electrode PE2, the third pixel electrode PE3, and the fourth pixel electrode PE4 may be adjacent to each other. For example, the first pixel electrode PE1 and the second pixel electrode PE2 may be adjacent to each other in a first direction DR1, the second pixel electrode PE2 and the third pixel electrode PE3 may be located adjacent to each other in the second direction DR2, and the third pixel electrode PE3 and the fourth pixel electrode PE4 may be adjacent to each other in the first direction DR1.

The bank BK may be located, for example, between adjacent pixel electrodes. For example, the bank BK may be located between the first pixel electrode PE1 and the second pixel electrode PE2. In addition, the bank BK may be located between the second pixel electrode PE2 and the third pixel electrode PE3. In addition, the bank BK may be located between the first pixel electrode PE1 and the fourth pixel electrode PE4. When the bank BK is located between all adjacent pixel electrodes, it may have a mesh shape that surrounds each of the first pixel electrode PE1, the second pixel electrode PE2, the third pixel electrode PE3, and the fourth pixel electrode PE4. In other words, the first pixel electrode PE1, the second pixel electrode PE2, the third pixel electrode PE3, and the fourth pixel electrode PE4 may be surrounded by the bank BK. For example, in plan view, the first pixel electrode PE1, the second pixel electrode PE2, the third pixel electrode PE3, and the fourth pixel electrode PE4 may be surrounded by the bank BK. In other words, the first pixel electrode PE1, the second pixel electrode PE2, the third pixel electrode PE3, and the fourth pixel electrode PE4 may be respectively located in areas (hereinafter, referred to as opening areas) defined by the bank BK. For example, the first pixel electrode PE1 may be located in a first opening area defined by the bank BK, the second pixel electrode PE2 may be located in a second opening area defined by the bank BK, the third pixel electrode PE3 may be located in a third opening area defined by the bank BK, and the fourth pixel electrode PE4 may be located in a fourth opening area defined by the bank BK.

In plan view as illustrated in FIG. 2, the bank BK may include a plurality of first extension portions EX1 extending along the first direction DR1 and a plurality of second extension portions EX2 extending along the second direction DR2. The first extension portions EX1 may cross the second extension portions EX2. The first extension portions EX1 and the second extension portions EX2 may be connected at crossing regions of the first extension portions EX1 and the second extension portions EX2. The first extension portions EX1 and the second extension portions EX2 may be integrally formed. The first pixel electrode PE1, the second pixel electrode PE2, the third pixel electrode PE3, and the fourth pixel electrode PE4 described above may be respectively located in the opening areas surrounded and defined by the first extension portions EX1 and the second extension portions EX2.

In plan view as illustrated in FIG. 2, the trenches TRC1 through TRC4 may be located between pixel electrodes and the bank BK, respectively. For example, a first trench TRC1 may be located between the first pixel electrode PE1 and the bank BK, a second trench TRC2 may be located between the second pixel electrode PE2 and the bank BK, a third trench TRC3 may be located between the third pixel electrode PE3 and the bank BK, and a fourth trench TRC4 may be located between the fourth pixel electrode PE4 and the bank BK. According to one or more embodiments, in plan view as illustrated in FIG. 2, the first trench TRC1 may surround the first pixel electrode PE1, the second trench TRC2 may surround the second pixel electrode PE2, the third trench TRC3 may surround the third pixel electrode PE3, and the fourth trench TRC4 may surround the fourth pixel electrode PE4. In addition, the first trench TRC1, the second trench TRC2, the third trench TRC3, and the fourth trench TRC4 may be surrounded by the bank BK.

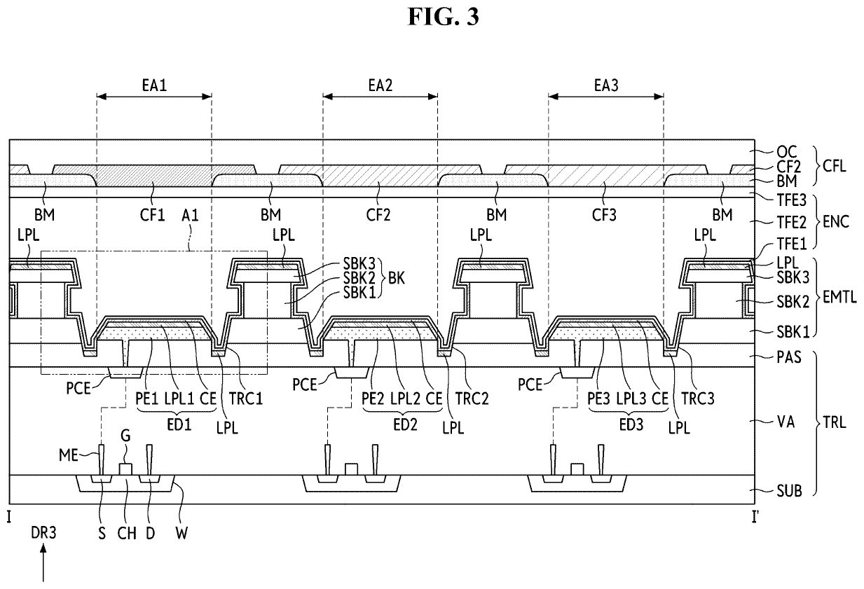

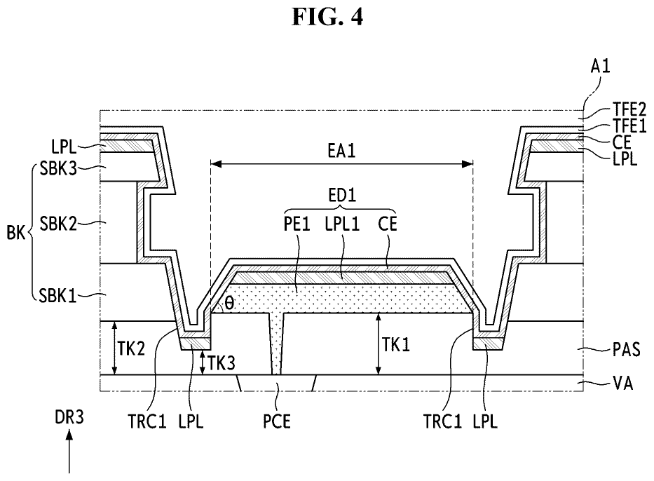

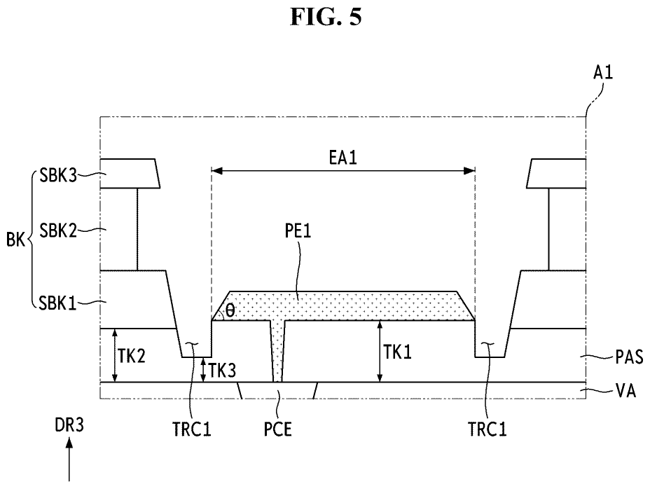

FIG. 3 is a cross-sectional view taken along the line I-I′ of FIG. 2. FIG. 4 is an enlarged view of area A1 of FIG. 3. FIG. 5 is a diagram obtained by removing a light-providing layer LPL and LPL1, a common electrode CE, a first encapsulating inorganic layer TFE1, and an encapsulating organic layer TFE2 from FIG. 4.

As illustrated in FIG. 3, the display device may include a transistor layer TRL, a light-emitting element layer EMTL, an encapsulation layer ENC, and a color filter layer CFL.

The substrate SUB may be a silicon substrate, a germanium substrate, or a silicon-germanium substrate. The base substrate SUB may be a substrate doped with a first-type impurity.

Well regions W may be located on the substrate SUB (or in the substrate SUB. The well regions W may be regions doped with a second-type impurity. The second-type impurity may be different from the first-type impurity described above. For example, when the first-type impurity is a p-type impurity, the second-type impurity may be an n-type impurity. On the other hand, when the first-type impurity is an n-type impurity, the second-type impurity may be a p-type impurity.

A source region S, a drain region D, and a channel region CH of a transistor TR may be located in each well region W. For example, a source region S (or a source electrode) and a drain region D (or a drain electrode) of a transistor TR may be located in each well region W. Each of the source region S and the drain region D may be a region doped with the first-type impurity described above. A gate electrode G of the transistor TR may cross and overlap each well region W. In plan view, each well region W crossing the gate electrode G may be divided into two regions, and the source region S may be located in one of the two regions, and the drain region D may be located in the other region. In other words, the source region S and the drain region D in each well region W may be respectively located on both sides of the gate electrode G with the gate electrode G interposed between them. The channel region CH of the transistor TR may be located in a part of each well region W which overlaps the gate electrode G.

The source region S may include a first lightly doped impurity region having a relatively lower impurity concentration than other parts of the source region S. In other words, a part of the source region S may include an impurity in a lower concentration than other parts of the source region S. The drain region D may include a second lightly doped impurity region having a relatively lower impurity concentration than other parts of the drain region D. In other words, a part of the drain region D may include an impurity in a lower concentration than other parts of the drain region D.

The first lightly doped impurity region and the second lightly doped impurity region may be located close to the channel region CH of the transistor TR. For example, the first lightly doped impurity region may be located close to the channel region CH to overlap a first spacer located on one side of the gate electrode G, and the second lightly doped impurity region may be located close to the channel region CH to overlap a second spacer located on the other side of the gate electrode G. A distance between a heavily doped impurity region of the source region S, and a heavily doped impurity region of the drain region D, may be increased by the first lightly doped impurity region and the second lightly doped impurity region. As the distance increases, a length of the channel region CH may eventually increase. Accordingly, punch-through and hot carrier phenomena due to a short channel can be reduced or prevented.

An interlayer insulating layer VA may be located on the substrate SUB (as used herein, “located on” may mean “above”). The interlayer insulating layer VA may include a plurality of insulating layers stacked along a third direction DR3.

An insulating layer PAS (hereinafter, referred to as a passivation layer PAS) may be located on the interlayer insulating layer VA.

The light-emitting element layer EMTL may be located on the passivation layer PAS. The light-emitting element layer EMTL may include, for example, a first light-emitting element ED1, a second light-emitting element ED2, a third light-emitting element ED3, and a fourth light-emitting element (e.g., a light-emitting element located in a fourth emission area of FIG. 2) located in different emission areas. For example, the first light-emitting element ED1 of the light-emitting element layer EMTL may be located in a first emission area EA1, the second light-emitting element ED2 of the light-emitting element layer EMTL may be located in a second emission area EA2, the third light-emitting element ED3 of the light-emitting element layer EMTL may be located in a third emission area EA3, and the fourth light-emitting element of the light-emitting element layer EMTL may be located in a fourth emission area EA4.

The first light-emitting element ED1, the second light-emitting element ED2, the third light-emitting element ED3, and the fourth light-emitting element may each provide white light.

The first light-emitting element ED1 may include the first pixel electrode PE1 (or a first anode), a first light-providing layer LPL1, and the common electrode CE stacked in the third direction DR3.

The second light-emitting element ED2 may include the second pixel electrode PE2 (or a second anode), a second light-providing layer LPL2, and the common electrode CE stacked in the third direction DR3.

The third light-emitting element ED3 may include the third pixel electrode PE3 (or a third anode), a third light-providing layer LPL3, and the common electrode CE stacked in the third direction DR3.

The fourth light-emitting element ED4 may include the fourth pixel electrode PE4 (or a fourth anode), a fourth light-providing layer, and the common electrode CE stacked in the third direction DR3.

Each of the first through third light-providing layers LPL1 through LPL3 and the fourth light-providing layer may include a plurality of light-emitting layers (e.g., organic light-emitting layers) that provide light of different colors, and the light-emitting layers may be stacked along the third direction DR3. Different light from the light-emitting layers may be mixed to generate white light. Each of the first through third light-providing layers LPL1 through LPL3 and the fourth light-providing layer may further include a charge generation layer.

Each of the first pixel electrode PE1, the second pixel electrode PE2, the third pixel electrode PE3, and the fourth pixel electrode PE4 may be connected to the source region S of a corresponding transistor TR through a pixel connection electrode PCE and a metal connection layer ME.

The first pixel electrode PE1 may be located to correspond to the first emission area EA1, the second pixel electrode PE2 may be located to correspond to the second emission area EA2, the third pixel electrode PE3 may be located to correspond to the third emission area EA3, and the fourth pixel electrode PE4 may be located to correspond to the fourth emission area. According to one or more embodiments, as illustrated in FIGS. 3 and 4, because each pixel electrode PE1, PE2, PE3, or PE4 does not overlap the bank BK, the area of each emission area EA1, EA2, or EA3 may increase, thereby improving an aperture ratio of a pixel.

An angle (e.g., taper angle) of inclined side surfaces of each pixel electrode PE1, PE2, PE3, or PE4 may be less than about 60 degrees. For example, as illustrated in FIG. 4 or 5, a taper angle θ of the first pixel electrode PE1 may be less than about 60 degrees. Here, the taper angle of the first pixel electrode PE1 may be an angle between a lower surface of the first pixel electrode PE1 and the side surfaces neighboring the lower surface. At this time, the lower surface of the first pixel electrode PE1 may be a surface facing the passivation layer PAS.

The bank BK may be located on the passivation layer PAS. For example, the bank BK located on the passivation layer PAS may surround the first pixel electrode PE1, the second pixel electrode PE2, the third pixel electrode PE3, and the fourth pixel electrode PE4. In cross section as illustrated in FIG. 3, the bank BK may protrude (or extend) from the passivation layer PAS along the third direction DR3.

The bank BK may include a plurality of sub-banks SBK1 through SBK3 stacked along the third direction DR3. For example, the bank BK may include a first sub-bank SBK1 on the passivation layer PAS, a second sub-bank SBK2 on the first sub-bank SBK1, and a third sub-bank SBK3 on the second sub-bank SBK2. In cross section, the second sub-bank SBK2 may be located between the first sub-bank SBK1 and the third sub-bank SBK3. A width of the second sub-bank SBK2 may be less than a width of the first sub-bank SBK1. In addition, the width of the second sub-bank SBK2 may be less than a width of the third sub-bank SBK3. Here, the width may be in a direction (e.g., the first direction DR1 and/or the second direction DR2) perpendicularly crossing a direction (e.g., the third direction DR3) in which the sub-banks SBK1 through SBK3 are stacked. Because the second sub-bank SBK2 has a smaller width than the third sub-bank SBK3 located thereon, edges of the third sub-bank SBK3 may surround the second sub-bank SBK2 in plan view, as illustrated in FIG. 2. In addition, because the second sub-bank SBK2 has a smaller width than the third sub-bank SBK3 located thereon, a cross section of the bank BK may have a reverse-tapered shape (or an overhang shape). In other words, because an uppermost sub-bank (e.g., the third sub-bank SBK3) located farthest from the passivation layer PAS (or the substrate SUB) among the first through third sub-banks SBK1 through SBK3 has a greater width than a sub-bank (e.g., the second sub-bank SBK2) directly underneath it, the cross section of the bank BK including the third sub-bank SBK3 and the second sub-bank SBK2 may have a reverse-tapered shape. The bank BK may be made of a material including inorganic matter. For example, the first sub-bank SBK1 may include a silicon oxide layer, the second sub-bank SBK2 may include a silicon nitride layer, and the third sub-bank SBK3 may include a silicon oxide layer. The second sub-bank SBK2 may also be made of a material including a metal.

The first trench TRC1, the second trench TRC2, the third trench TRC3, and the fourth trench TRC4 may be located in an upper surface of the passivation layer PAS. For example, the first trench TRC1, the second trench TRC2, the third trench TRC3, and the fourth trench TRC4 may be sunken from the upper surface of the passivation layer PAS toward a lower surface of the passivation layer PAS. In other words, the first trench TRC1, the second trench TRC2, the third trench TRC3, and the fourth trench TRC4 may be sunken into the passivation layer PAS along a direction opposite to the direction (e.g., the third direction DR3) in which the above-described bank BK protrudes. Here, the upper surface and the lower surface of the passivation layer PAS may be surfaces of the passivation layer PAS which face each other in a thickness direction (e.g., the third direction DR3) of the passivation layer PAS. At this time, the lower surface among the upper surface and the lower surface of the passivation layer PAS may be located closer to the substrate SUB. Because the first trench TRC1, the second trench TRC2, the third trench TRC3, and the fourth trench TRC4 are located in the upper surface of the passivation layer PAS as described above, the upper surface of the passivation layer PAS may have an uneven shape. For example, at least a portion of the passivation layer PAS may have different thicknesses. According to one or more embodiments, the passivation layer PAS may have a smaller thickness in areas overlapping the first trench TRC1, the second trench TRC2, the third trench TRC3, and the fourth trench TRC4 than in areas overlapping the pixel electrodes PE1 through PE4 and the bank BK. For example, as illustrated in FIGS. 4 and 5, a thickness TK2 of the passivation layer PAS in an area overlapping the bank BK may be greater than a thickness TK3 of the passivation layer PAS in an area overlapping the first trench TRC1, and less than a thickness TK1 of the passivation layer PAS in an area overlapping the first pixel electrode PE1.

The trenches TRC1 through TRC4 may be formed, for example, by removing a portion of the passivation layer PAS during an etching process for forming the pixel electrodes PE1 through PE4. Here, the etching process may use dry etching or wet etching.

The light-providing layer LPL1, LPL2, LPL3 and LPL may be broken for each emission area by the bank BK having an overhang structure and the sunken trenches TRC1 through TRC4. In other words, during a process of depositing a light-providing material layer to form the light-providing layer LPL1, LPL2, LPL3 and LPL, the light-providing material layer may be broken by the bank BK and the trenches TRC1 through TRC4. Accordingly, the first light-providing layer LPL1, the second light-providing layer LPL2, the third light-providing layer LPL3, and the fourth light-providing layer may be located on the first pixel electrode PE1, the second pixel electrode PE2, the third pixel electrode PE3, and the fourth pixel electrode PE4 in the emission areas EA1, EA2, EA3, and EA4, respectively. At this time, the light-providing layer LPL may also be located on the bank BK and may also be located inside the trenches TRC1 through TRC4. The first light-providing layer LPL1, the second light-providing layer LPL2, the third light-providing layer LPL3, the fourth light-providing layer, the light-providing layer LPL on the bank BK, and the light-providing layer LPL inside the trenches TRC1 through TRC4 may be kept separate from each other due to the bank BK and the trenches TRC1 through TRC4. Therefore, lateral leakage current between adjacent light-providing layers on pixel electrodes can be reduced or minimized, thereby reducing or preventing color mixing between adjacent pixels. For example, the amount of lateral leakage current that can flow from the first light-providing layer LPL1 on the first pixel electrode PE1 to the second light-providing layer LPL2 on the second pixel electrode PE2 can be reduced or minimized. Accordingly, the image quality of the display device can be improved.

The first through third light-providing layers LPL1 through LPL3, the fourth light-providing layer, the light-providing layer LPL on the bank BK, and the light-providing layer LPL in the trenches TRC1 through TRC4 may include a plurality of stack layers. For example, each light-providing layer may include a first stack layer, a second stack layer, and a third stack layer stacked in the third direction DR3. Each stack layer may provide light of a different wavelength. For example, the first stack layer, the second stack layer, and the third stack layer may emit light of different respective colors. For example, the light-providing layer LPL may have a tandem structure in which a plurality of stack layers providing light of different respective colors are stacked in a vertical direction (e.g., the third direction DR3).

The first stack layer may be located on each pixel electrode PE1, PE2, PE3, or PE4 and the bank BK, and may be located inside the trenches TRC1 through TRC4. The first stack layer may include a first organic light-emitting layer, a hole-transporting layer, and an electron-transporting layer.

The second stack layer may be located on the first stack layer. The second stack layer may include a second organic light-emitting layer, a hole-transporting layer, and an electron-transporting layer.

The third stack layer may be located on the second stack layer. The third stack layer may include a third organic light-emitting layer, a hole-transporting layer, and an electron-transporting layer.

Each of the first through third light-emitting elements ED1 through ED3 and the fourth light-emitting element may provide white light by mixing light of a first color (e.g., red) from the first stack layer, light of a second color (e.g., green) from the second stack layer, and light of a third color (e.g., blue) from the third stack layer. For example, each of the first light-emitting element ED1, the second light-emitting element ED2, the third light-emitting element ED3, and the fourth light-emitting element may provide white light.

In addition, the first through third light-providing layers LPL1 through LPL3, the fourth light-providing layer, the light-providing layer LPL on the bank BK, and the light-providing layer LPL in the trenches TRC1 through TRC4 may further include at least one charge generation layer in addition to the stack layers described above. The charge generation layer may be located, for example, between stack layers adjacent to each other in the third direction DR3. The charge generation layer may include, for example, a first charge generation layer and a second charge generation layer stacked in the third direction DR1. In this case, the first charge generation layer may be located between the first stack layer and the second stack layer, and the second charge generation layer may be located between the second stack layer and the third stack layer.

Each charge generation layer may include a negative charge generation layer and a positive charge generation layer. For example, the first charge generation layer may include a first negative charge generation layer and a first positive charge generation layer stacked in the third direction DR3, and the second charge generation layer may include a second negative charge generation layer and a second positive charge generation layer stacked in the third direction DR3.

The common electrode CE may be located on the first through third light-providing layers LPL1 through LPL3, the fourth light-providing layer, the light-providing layer LPL on the bank BK, and the light-providing layer LPL in the trenches TRC1 through TRC4. For example, the common electrode CE may be located on each light-providing layer to overlap the first pixel electrode PE1, the second pixel electrode PE2, the third pixel electrode PE3, the fourth pixel electrode PE4, the first emission area EA1, the second emission area EA2, the third emission area EA3, the fourth emission area EA4, and the bank BK. In a top emission structure, the common electrode CE may be made of a transparent conductive material (TCO) that can transmit light, such as indium tin oxide (ITO) or indium zinc oxide (IZO), or a semi-transmissive conductive material, such as magnesium (Mg), silver (Ag) or an alloy of Mg and Ag. When the common electrode CE is made of a semi-transmissive conductive material, light output efficiency may be increased by a microcavity.

The encapsulation layer ENC may be located on the common electrode CE.

The encapsulation layer ENC may cover upper and side surfaces of the light-emitting element layer EMTL, and may protect the light-emitting element layer EMTL. The encapsulation layer ENC may include at least one inorganic layer and at least one organic layer to encapsulate the light-emitting element layer EMTL. The encapsulation layer ENC may include at least one inorganic layer TFE1 and TFE3 to reduce or prevent permeation of oxygen or moisture into the light-emitting element layer EMTL. In addition, the encapsulation layer ENC may include at least one organic layer to protect the light-emitting element layer EMTL from foreign substances, such as dust.

For example, the encapsulation layer ENC may include the first encapsulating inorganic layer TFE1, the encapsulating organic layer TFE2, and a second encapsulating inorganic layer TFE3.

The first encapsulating inorganic layer TFE1 may be located on the common electrode CE, the encapsulating organic layer TFE2 may be located on the first encapsulating inorganic layer TFE1, and the second encapsulating inorganic layer TFE3 may be located on the encapsulating organic layer TFE2. Each of the first encapsulating inorganic layer TFE1 and the second encapsulating inorganic layer TFE3 may be a multilayer in which one or more inorganic layers selected from a silicon nitride layer, a silicon oxynitride layer, a silicon oxide layer, a titanium oxide layer, and an aluminum oxide layer are alternately stacked. The encapsulating organic layer TFE2 may be an organic layer, such as acryl resin, epoxy resin, phenolic resin, polyamide resin, or polyimide resin.

A capping layer may be further located between the common electrode CE and the encapsulation layer ENC (e.g., the first encapsulating inorganic layer TFE1) described above. The capping layer may include an inorganic insulating material. In one or mor embodiments, the capping layer may include aluminum oxide, titanium oxide, tantalum oxide, hafnium oxide, zinc oxide, silicon oxide, silicon nitride, and/or silicon oxynitride.

A light-blocking layer BM may be located on the encapsulation layer ENC. For example, the light-blocking layer BM may be located on the encapsulation layer ENC to overlap the bank BK. The light-blocking layer BM may not overlap each of the emission areas EA1 through EA4. In other words, the light-blocking layer BM may be located on the encapsulation layer ENC not to overlap each of the emission areas EA1 through EA4. The light-blocking layer BM may include a light-absorbing material. For example, the light-blocking layer BM may include an inorganic black pigment or an organic black pigment. The inorganic black pigment may be carbon black, and the organic black pigment may include at least one of lactam black, perylene black, and/or aniline black, but the present disclosure is not limited thereto. The light-blocking layer BM may reduce or prevent color mixing by reducing or preventing intrusion of visible light between the first through fourth emission areas EA1 through EA4, thereby improving a color gamut of the display device.

The display device may include a plurality of color filters CF1 through CF3 located on the emission areas EA1 through EA4. The color filters CF1 through CF3 may be located to correspond to the emission areas EA1 through EA3, respectively. For example, the color filters CF1 through CF3 may be located on the light-blocking layer BM to overlap the emission areas EA1 through EA3. A color filter located to correspond to the fourth emission area EA4 may have, for example, the same color as the color filter located to correspond to the third emission area EA3.

The color filters CF1 through CF3 may include a first color filter CF1, a second color filter CF2, and a third color filter CF3 located to correspond to different emission areas EA1 through EA3, respectively. Each of the color filters CF1 through CF3 may include a colorant, such as a dye or pigment that absorbs light of wavelengths other than light of a specific wavelength and may be located to correspond to the color of light emitted from an emission area EA1, EA2 or EA3. For example, the first color filter CF1 may overlap the first emission area EA1 and may be a red color filter that transmits only red first light. The second color filter CF2 may overlap the second emission area EA2 and may be a green color filter that transmits only green second light. The third color filter CF3 may overlap the third emission area EA3 and may be a blue color filter that transmits only blue third light. The color filter located in the fourth emission area may be a blue color filter.

The color filters CF1 through CF3 may be spaced apart from adjacent other color filters CF1 through CF3 on the light-blocking layer BM. However, the present disclosure is not limited thereto. For example, the color filters CF1 through CF3 may also partially overlap adjacent other color filters CF1 through CF3 on the light-blocking layer BM. Because the color filters CF1 through CF3 overlap, the intensity of reflected light due to external light may be reduced. Furthermore, the color of the reflected light due to the external light may be controlled by adjusting the arrangement, shapes and areas of the color filters CF1 through CF3 in plan view.

An overcoat layer OC may be located on the color filters CF1 through CF3 to planarize the top of the color filters CF1 through CF3. The overcoat layer OC may be a colorless light-transmitting layer that does not have a color in a visible light band. For example, the overcoat layer OC may include a colorless light-transmitting organic material, such as acrylic resin.

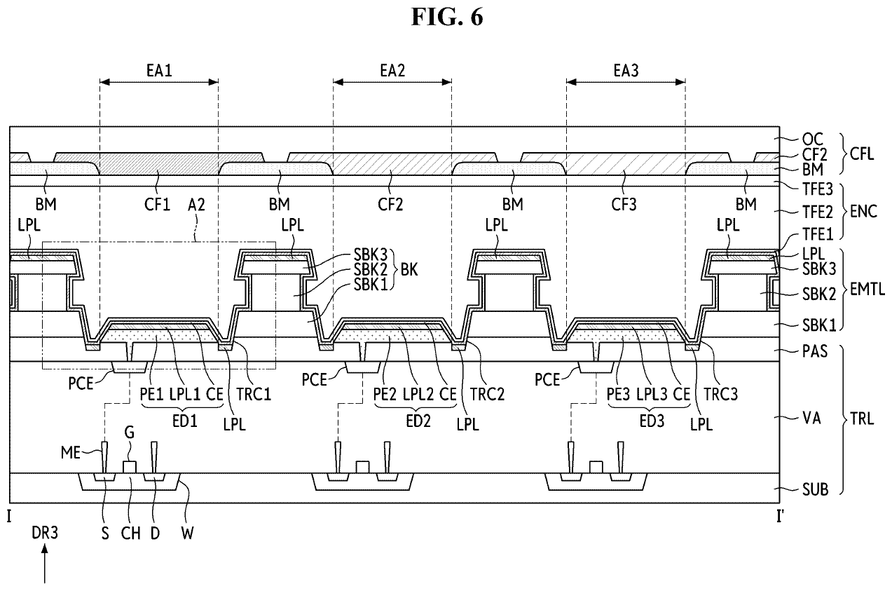

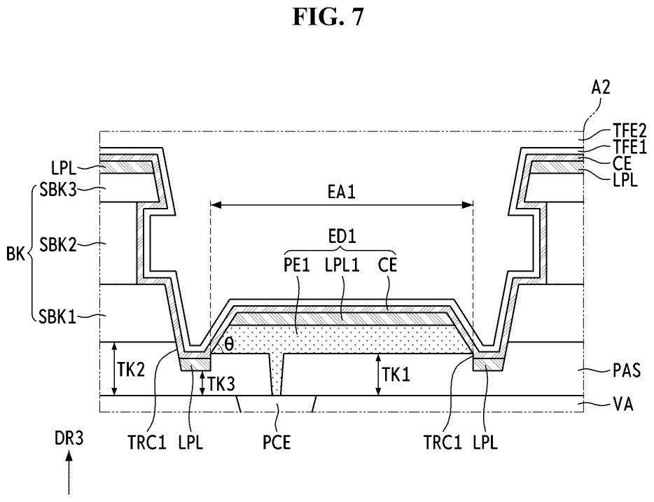

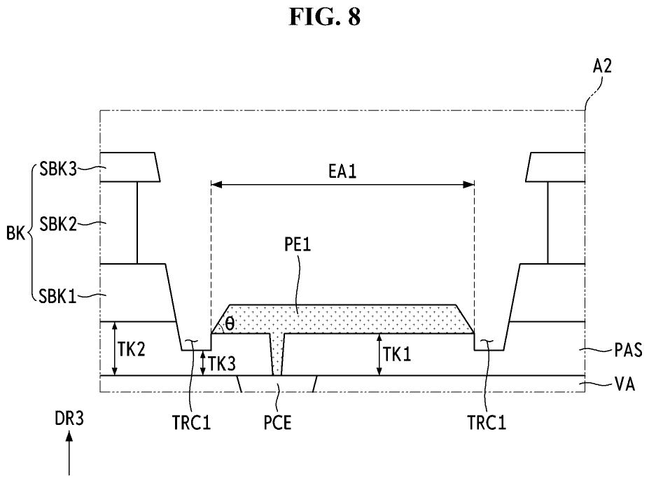

FIG. 6 is a cross-sectional view of one or more embodiments taken along the line I-I′ of FIG. 2. FIG. 7 is an enlarged view of area A2 of FIG. 6. FIG. 8 is a diagram obtained by removing a light-providing layer LPL and LPL1, a common electrode CE, a first encapsulating inorganic layer TFE1, and an encapsulating organic layer TFE2 from FIG. 7.

The display device of FIGS. 6 through 8 is different from the display device of FIGS. 3 through 5 described above with respect to a thickness of a passivation layer PAS. Therefore, this difference will be mainly described as follows.

As illustrated in FIGS. 6 through 8, a thickness TK1 of the passivation layer PAS in an area overlapping a first pixel electrode PE1 may be greater than a thickness TK3 of the passivation layer PAS in an area overlapping a first trench TRC1, and may be less than a thickness TK2 of the passivation layer PAS in an area overlapping a bank BK.

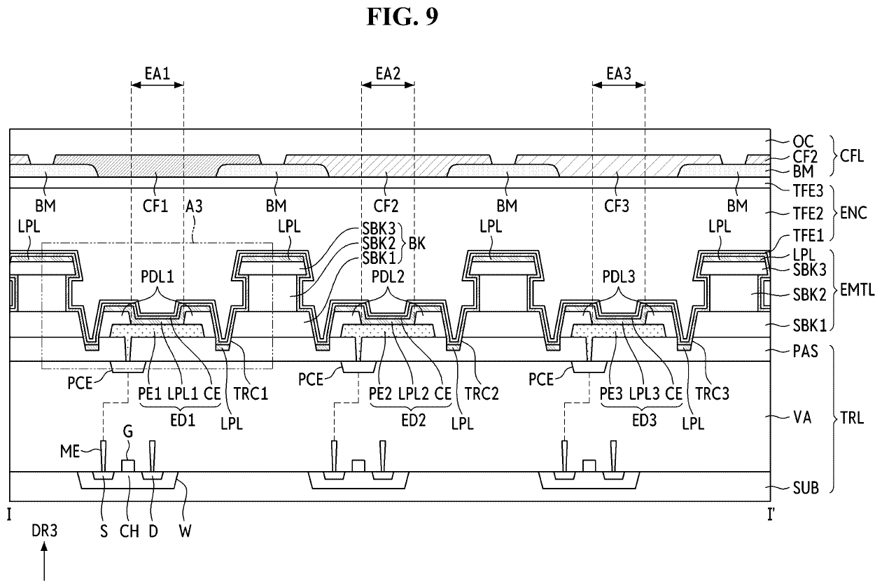

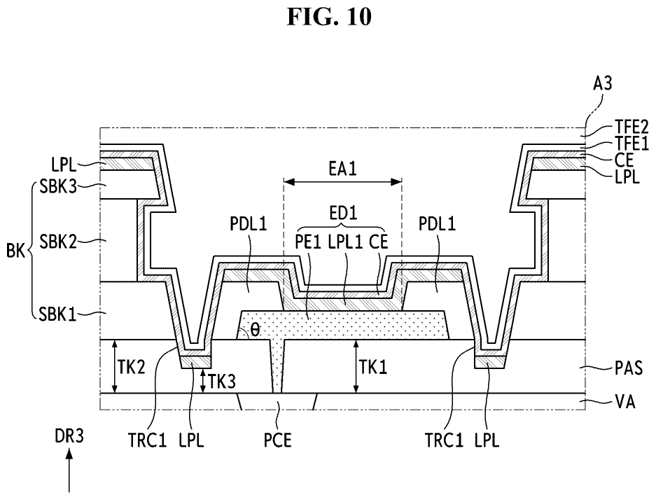

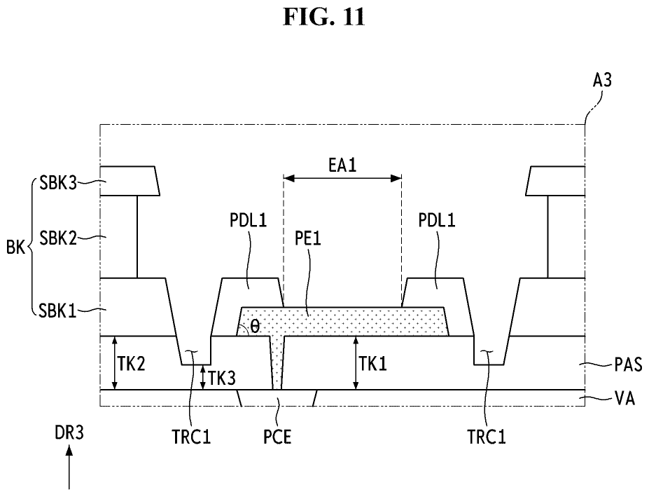

FIG. 9 is a cross-sectional view of one or more embodiments taken along the line I-I′ of FIG. 2. FIG. 10 is an enlarged view of area A3 of FIG. 9. FIG. 11 is a diagram obtained by removing a light-providing layer LPL and LPL1, a common electrode CE, a first encapsulating inorganic layer TFE1, and an encapsulating organic layer TFE2 from FIG. 10.

The display device of FIGS. 9 through 11 is different from the display device of FIGS. 3 through 5 described above with respect to a thickness of a passivation layer PAS and a pixel-defining layer. Therefore, this difference will be mainly described as follows.

As illustrated in FIGS. 9 through 11, a first pixel-defining layer PDL1, a second pixel-defining layer PDL2, and a third pixel-defining layer PDL3 may be further located on a first pixel electrode PE1, a second pixel electrode PE2, and a third pixel electrode PE3, respectively. A fourth pixel-defining layer may be further located on a fourth pixel electrode PE4.

The first pixel-defining layer PDL1, the second pixel-defining layer PDL2, the third pixel-defining layer PDL3, and the fourth pixel-defining layer may define emission areas EA1 through EA4 of pixels, respectively. To this end, the first pixel-defining layer PDL1, the second pixel-defining layer PDL2, the third pixel-defining layer PDL3, and the fourth pixel-defining layer may be, for example, located on the passivation layer PAS to partially expose the first pixel electrode PE1, the second pixel electrode PE2, the third pixel electrode PE3, and the fourth pixel electrode PE4, respectively. The first pixel-defining layer PDL1, the second pixel-defining layer PDL2, the third pixel-defining layer PDL3, and the fourth pixel-defining layer may cover edges of the first pixel electrode PE1, the second pixel electrode PE2, the third pixel electrode PE3, and the fourth pixel electrode PE4, respectively. In other words, a portion of the first pixel electrode PE1 (e.g., edges of the first pixel electrode PE1) may overlap the first pixel-defining layer PDL1, a portion of the second pixel electrode PE2 (e.g., edges of the second pixel electrode PE2) may overlap the second pixel-defining layer PDL2, a portion of the third pixel electrode PE3 (e.g., edges of the third pixel electrode PE3) may overlap the third pixel-defining layer PDL3, and a portion of the fourth pixel electrode PE4 may overlap the fourth pixel-defining layer described above. The first pixel-defining layer PDL1, the second pixel-defining layer PDL2, the third pixel-defining layer PDL3, and the fourth pixel-defining layer may be made of an organic layer, such as acryl resin, epoxy resin, phenolic resin, polyamide resin, or polyimide resin.

In plan view, the pixel-defining layers PDL1 through PDL3 may be surrounded by trenches TRC1 through TRC3, respectively. For example, in plan view, edges of the first pixel-defining layer PDL1 may be surrounded by a first trench TRC1, edges of the second pixel-defining layer PDL2 may be surrounded by a second trench TRC2, edges of the third pixel-defining layer PDL3 may be surrounded by a third trench TRC3, and edges of the fourth pixel-defining layer may be surrounded by a fourth trench TRC4.

As illustrated in FIGS. 9 through 11, a first light-providing layer LPL1 may be located on the first pixel electrode PE1 and the first pixel-defining layer PDL1, a second light-providing layer LPL2 may be located on the second pixel electrode PE2 and the second pixel-defining layer PDL2, a third light-providing layer LPL3 may be located on the third pixel electrode PE3 and the third pixel-defining layer PDL3, and a fourth light-providing layer may be located on the fourth pixel electrode PE4 and the fourth pixel-defining layer.

As illustrated in FIGS. 9 through 11, a thickness TK1 of the passivation layer PAS in an area overlapping the first pixel electrode PE1 may be greater than a thickness TK3 of the passivation layer PAS in an area overlapping the first trench TRC1, and may be substantially equal to a thickness TK2 of the passivation layer PAS in an area overlapping a bank BK.

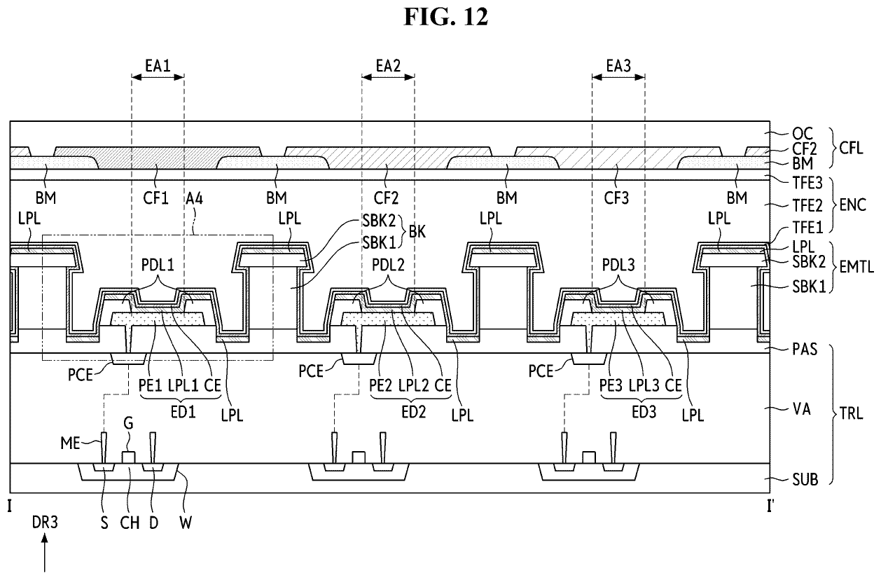

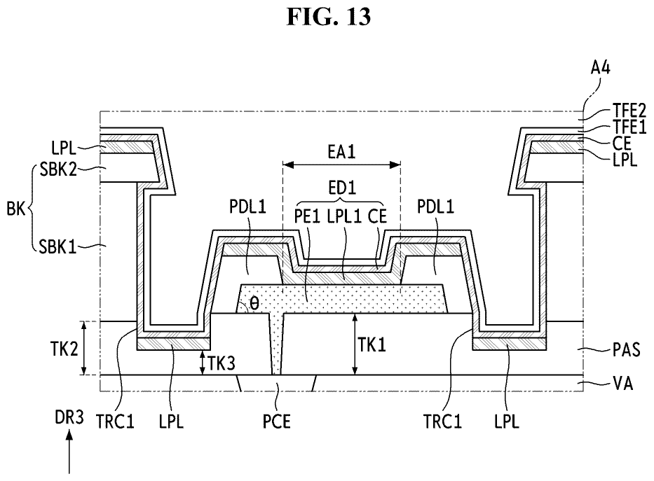

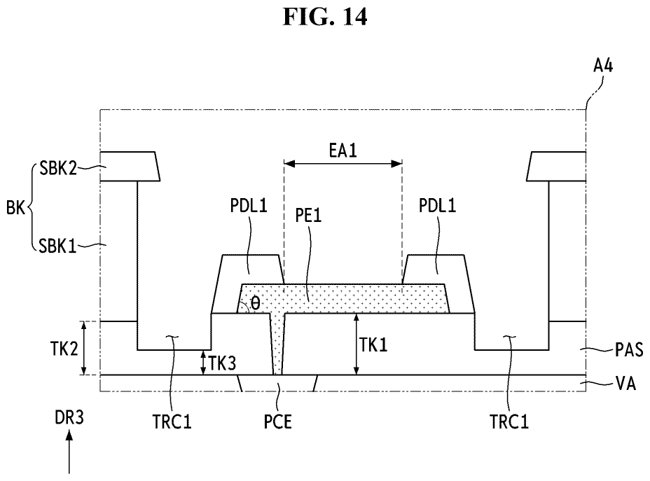

FIG. 12 is a cross-sectional view of one or more embodiments taken along the line I-I′ of FIG. 2. FIG. 13 is an enlarged view of area A4 of FIG. 12. FIG. 14 is a diagram obtained by removing a light-providing layer LPL and LPL1, a common electrode CE, a first encapsulating inorganic layer TFE1, and an encapsulating organic layer TFE2 from FIG. 13.

The display device of FIGS. 12 through 14 is different from the display device of FIGS. 9 through 11 described above with respect to a bank BK. Therefore, this difference will be mainly described as follows.

As illustrated in FIGS. 12 through 14, the bank BK may include a first sub-bank SBK1 and a second sub-bank SBK2. The first sub-bank SBK1 may be located on a passivation layer PAS, and the second sub-bank SBK2 may be located on the first sub-bank SBK1.

In cross section, the first sub-bank SBK1 may be located between the passivation layer PAS and the second sub-bank SBK2. A width of the first sub-bank SBK1 may be less than a width of the second sub-bank SBK2. Here, the width may be a size in a direction (e.g., the first direction DR1 and/or the second direction DR2) perpendicularly crossing a direction (e.g., the third direction DR3) in which the sub-banks SBK1 and SBK2 are stacked. Because the first sub-bank SBK1 has a smaller width than the second sub-bank SBK2 located thereon, edges of the second sub-bank SBK2 may surround the first sub-bank SBK1 in plan view. In addition, because the first sub-bank SBK1 has a smaller width than the second sub-bank SBK2 located thereon, a cross section of the bank BK may have a reverse-tapered shape (or an overhang shape). In other words, because an uppermost sub-bank (e.g., the second sub-bank SBK2) located farthest from the passivation layer PAS (or a substrate SUB) among the first and second sub-banks SBK1 and SBK2 has a greater width than a sub-bank (e.g., the first sub-bank SBK1) directly underneath it, the cross section of the bank BK including the first sub-bank SBK1 and the second sub-bank SBK2 may have a reverse-tapered shape. The bank BK may be made of a material including inorganic matter. For example, the first sub-bank SBK1 may include a silicon nitride layer, and the second sub-bank SBK2 may include a silicon oxide layer. The first sub-bank SBK1 may also be made of a material including a metal.

As illustrated in FIGS. 12 through 14, a thickness TK2 of the passivation layer PAS in an area overlapping the bank BK may be greater than a thickness TK3 of the passivation layer PAS in an area overlapping a first trench TRC1, and may be less than a thickness TK1 of the passivation layer PAS in an area overlapping a first pixel electrode PE1.

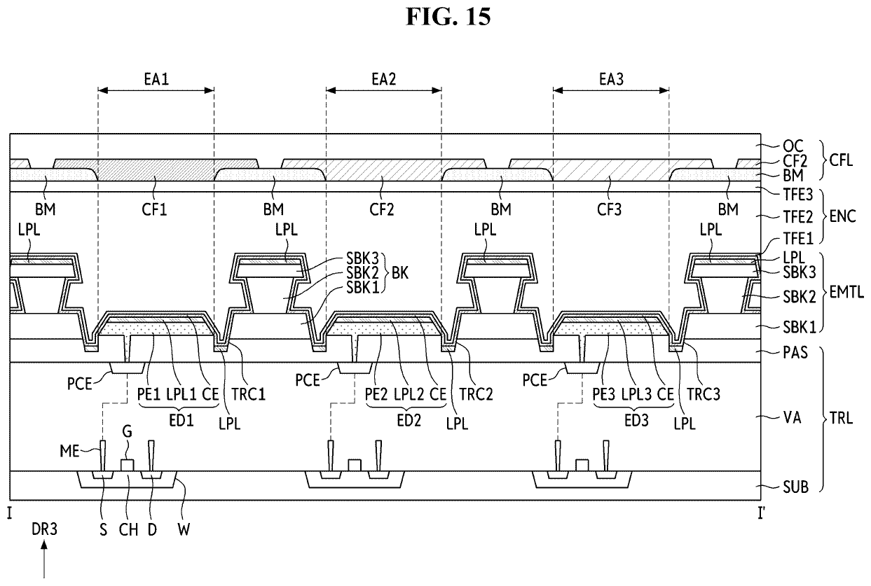

FIG. 15 is a cross-sectional view of one or more embodiments taken along the line I-I′ of FIG. 2.

The display device of FIG. 15 is different from the display device of FIG. 3 described above with respect to a bank BK. Therefore, this difference will be mainly described as follows.

As illustrated in FIG. 15, a second sub-bank SBK2 of the bank BK may have a width that gradually increases from a lower surface to an upper surface thereof. For example, the second sub-bank SBK2 may have an inverted trapezoidal shape. Here, the lower surface of the second sub-bank SBK2 may be a surface facing a first sub-bank SBK1, and the upper surface of the second sub-bank SBK2 may be a surface facing a third sub-bank SBK3.

Because the second sub-bank SBK2 has an inverted trapezoidal shape (or a reverse-tapered shape), a light-providing layer can be more easily broken for each emission area.

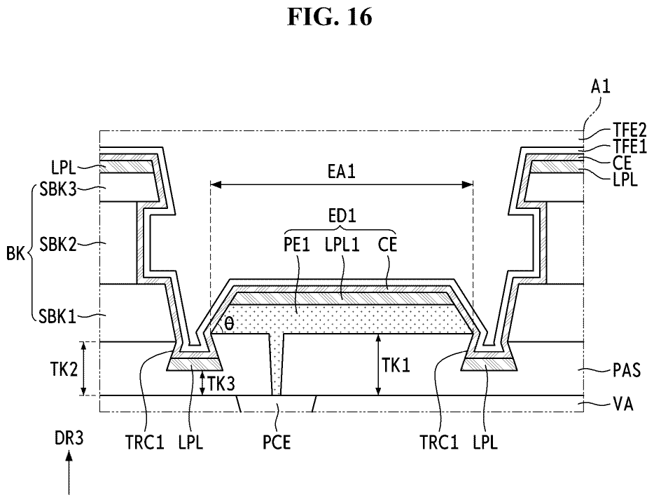

FIG. 16 is an enlarged view of one or more embodiments of area A1 of FIG. 3.

The display device of FIG. 16 is different from the display device of FIG. 4 described above with respect to a first trench TRC1. Therefore, this difference will be mainly described as follows.

As illustrated in FIG. 16, the first trench TRC1 may have a width that gradually decreases along a direction (e.g., the third direction DR3) from a passivation layer PAS toward a first pixel electrode PE1. Accordingly, a portion of the passivation layer PAS, which defines inner walls of the first trench TRC1, may have a reverse-tapered shape. Accordingly, a light-providing layer LPL and LPL1 can be more easily broken inside the first trench TRC1.

At least one of a second trench TRC2, a third trench TRC3, and a fourth trench TRC4 may have a shape similar to that of the first trench TRC1 of FIG. 16.

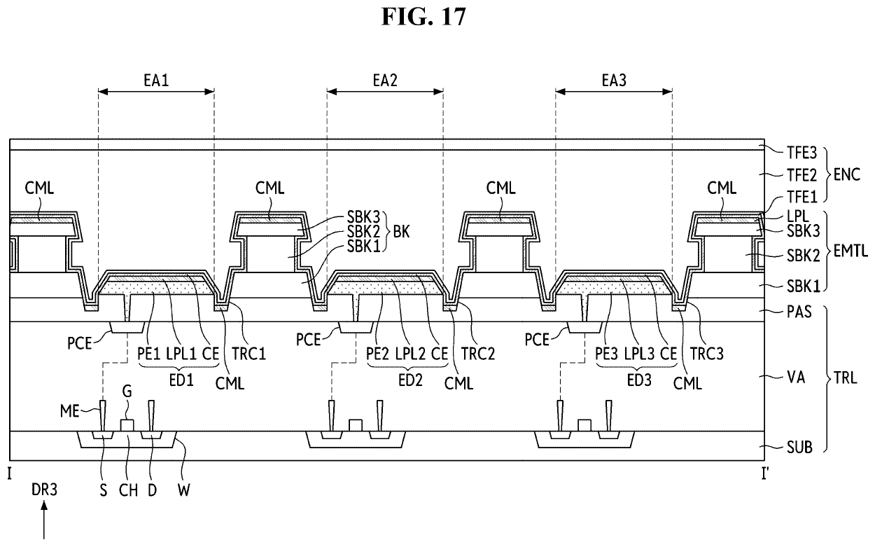

FIG. 17 is a cross-sectional view of one or more embodiments taken along the line I-I′ of FIG. 2.

The display device of FIG. 17 is different from the display device of FIGS. 3 through 5 described above with respect to a light-providing layer. Therefore, this difference will be mainly described as follows.

A first light-providing layer LPL1 of FIG. 17 may provide light of a first color (e.g., red), a second light-providing layer LPL2 may provide light of a second color (e.g., green), and a third light-providing layer LPL3 may provide light of a third color (e.g., blue).

The first light-providing layer LPL1 may include a first organic light-emitting layer that provides the first color, the second light-providing layer LPL2 may include a second organic light-emitting layer that provides the second color, and the third light-providing layer LPL3 may include a third organic light-emitting layer that provides the third color. In addition, each of the first light-providing layer LPL1, the second light-providing layer LPL2, and the third light-providing layer LPL3 may further include a common layer CML to be described later.

As illustrated in FIG. 17, the common layer CML may be located on a bank BK. In addition, the common layer CML may be located in each of first through fourth trenches TRC1 through TRC4. The common layer CML may include, for example, at least one of a hole-transporting layer HTL and/or a hole-injecting layer PHIL. The common layer CML may be broken by the bank BK and the trenches TRC1 through TRC4. Accordingly, the common layer CML on the bank BK, each common layer in the trenches TRC1 through TRC4, the common layer CML on a first pixel electrode PE1, the common layer CML on a second pixel electrode PE2, and the common layer CML on a third pixel electrode PE3 may be separated without being connected to each other.

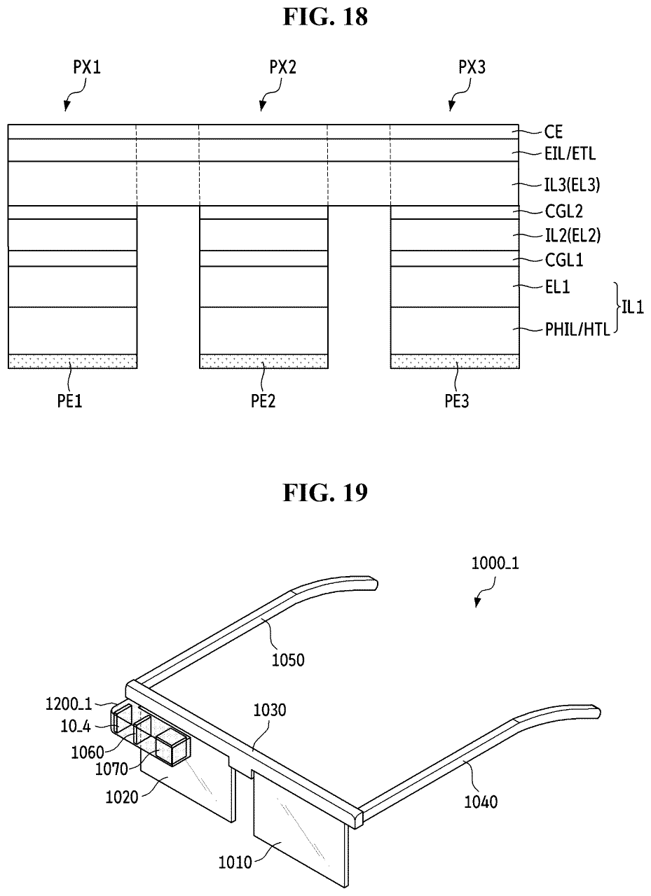

FIG. 18 is a diagram for explaining the breaking of a light-providing layer by a bank BK and trenches.

Referring to FIG. 18, a light-providing layer having a three-tandem structure (e.g., at least one of LPL1, LPL2, and/or LPL3) may be located on a first pixel electrode PE1 of a first pixel, a second pixel electrode PE2 of a second pixel, and a third pixel electrode PE3 of a third pixel.

In the three-tandem structure, the light-providing layer (e.g., at least one of LPL1, LPL2 and/or LPL3) may have a tandem structure including a plurality of stack layers IL1 through IL3 that emit different light. For example, the light-providing layer (e.g., at least one of LPL1, LPL2 and/or LPL3) may include a first stack layer IL1 that emits light of a first color, a second stack layer IL2 that emits light of a second color, and a third stack layer IL3 that emits light of a third color. The first stack layer IL1, the second stack layer IL2, and the third stack layer IL3 may be sequentially stacked. A first charge generation layer CGL1 may be located between the first stack layer IL1 and the second stack layer IL2, and a second charge generation layer CGL2 may be located between the second stack layer IL2 and the third stack layer IL3.

The first stack layer IL1 may have a structure in which a hole-transporting layer HTL or a hole-injecting layer PHIL and a first organic light-emitting layer EL1, which emits light of the first color, are sequentially stacked.

The second stack layer IL2 may include a second organic light-emitting layer EL2 that emits light of the second color.

The first charge generation layer CGL1 may be located between the first stack layer IL1 and the second stack layer IL2 to supply charges to the second stack layer IL2 and electrons to the first stack layer IL1. The first charge generation layer CGL1 may include an n-type charge generation layer that supplies electrons to the first stack layer IL1, and a p-type charge generation layer that supplies holes to the second stack layer IL2. The n-type charge generation layer may include a dopant of a metal material.

The third stack layer IL3 may include a third organic light-emitting layer EL3 that emits light of the third color.

The second charge generation layer CGL2 may be located between the second stack layer IL2 and the third stack layer IL3 to supply charges to the third stack layer IL3 and electrons to the second stack layer IL2. The second charge generation layer CGL2 may include an n-type charge generation layer that supplies electrons to the second stack layer IL2, and a p-type charge generation layer that supplies holes to the third stack layer IL3.

An electron-injecting layer EIL (or an electron-transporting layer ETL) may be located on the third stack layer IL3, and a common electrode CE may be located on the electron-injecting layer EIL (or the electron-transporting layer ETL).

As illustrated in FIG. 18, the hole-injecting layer PHIL, the hole-transporting layer HTL, the first organic light-emitting layer EL1, the first charge generation layer CGL1, the second organic light-emitting layer EL2, and the second charge generation layer CGL2 of the light-providing layer (e.g., at least one of LPL1, LPL2 and/or LPL3) may be broken by the bank BK and the trenches.

The display device described above can be applied to a head-mounted display device, which will be described with reference to FIG. 19 as follows.

FIG. 19 is a perspective view of a head-mounted display device 1000_1 according to one or more embodiments.

Referring to FIG. 19, the head-mounted display device 1000_1 according to one or more embodiments may be a glasses-type display device in which a display device housing 1200_1 is implemented to be lightweight and small. The head-mounted display device 1000_1 according to one or more embodiments may include a display device 10_4, a left lens 1010, a right lens 1020, a support frame 1030, eyeglass frame legs 1040 and 1050, an optical member 1600, an optical path conversion member 1070, and the display device housing 1200_1.

The display device housing 1200_1 may include the display device 10_4, the optical member 1600, and the optical path conversion member 1070. An image displayed on the display device 10_4 may be enlarged by the optical member 1600, may have its optical path converted by the optical path conversion member 1070, and then may be provided to a user's right eye through the right lens 1020. Accordingly, the user can view, through the right eye, an augmented reality image into which a virtual image displayed on the display device 10_4 and a real image viewed through the right lens 1020 are combined.

Although the display device housing 1200_1 is located at a right end of the support frame 1030 in FIG. 19, embodiments of the present specification are not limited thereto. For example, the display device housing 1200_1 may also be located at a left end of the support frame 1030. In this case, an image of the display device 10_4 may be provided to a user's left eye. Alternatively, the display device housing 1200_1 may be located at both the left and right ends of the support frame 1030. In this case, the user can view an image displayed on the display device 10_4 through both the left and right eyes.

A display device according to the present disclosure can reduce or prevent color mixing between adjacent pixels by reducing or minimizing lateral leakage current between the adjacent pixels. Therefore, the image quality of the display device can be improved.

However, the aspects of the present disclosure are not restricted to the one set forth herein. The above and other aspects of the present disclosure will become more apparent to one of daily skill in the art to which the present disclosure pertains by referencing the claims.

The display device according to the embodiment can be applied to various electronic devices. The electronic device according to one embodiment includes the display device described above and may further include modules or devices having additional functions in addition to the display device.

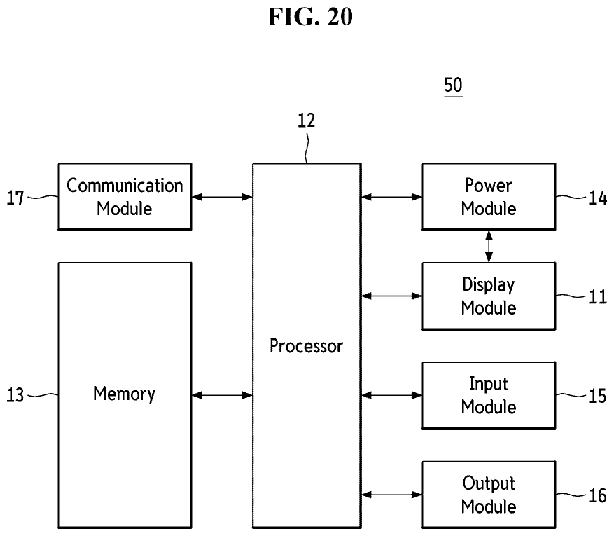

FIG. 20 is a block diagram of an electronic device according to one embodiment. Referring to FIG. 20, the electronic device 50 according to one embodiment may include a display module, a processor 12, a memory 13, and a power module 14. The electronic device 5000 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 5000 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 11 other than the display device.

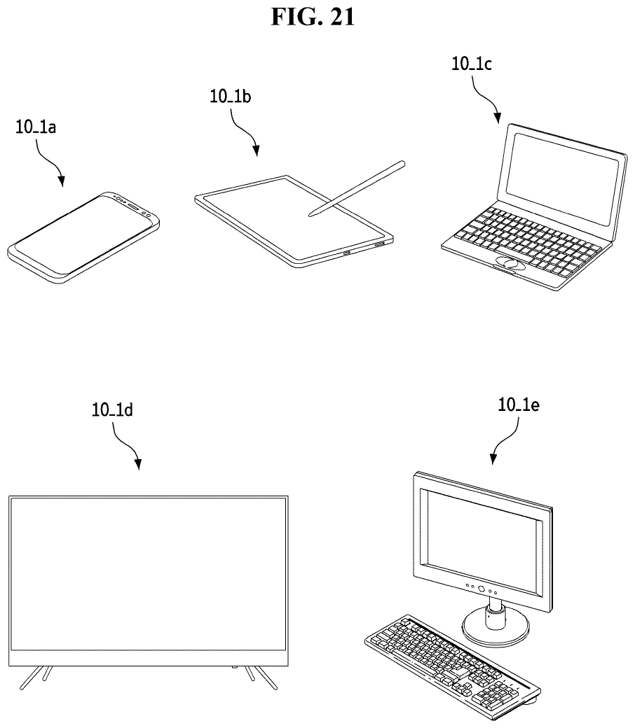

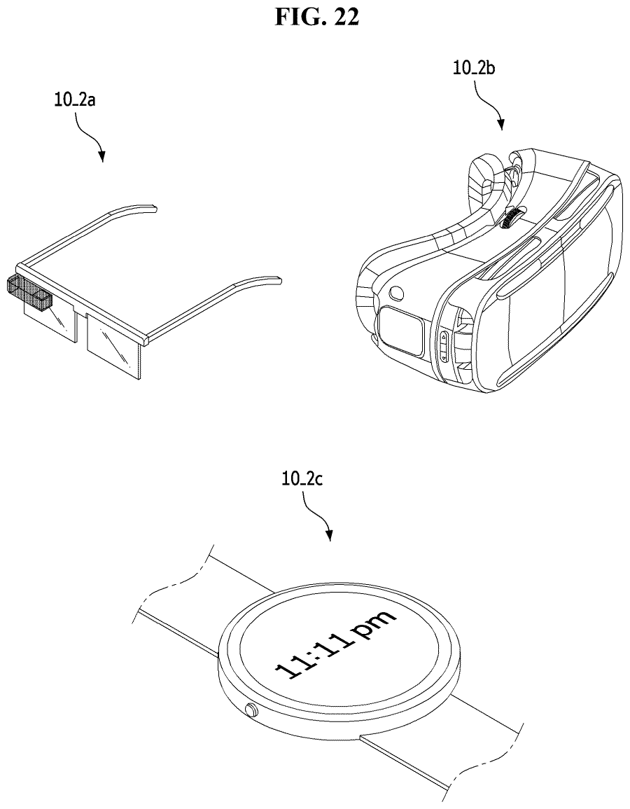

FIGS. 21, 22, and 23 are schematic diagrams of electronic devices according to various embodiments. FIGS. 21 to 23 illustrate examples of various electronic devices to which the display device according to the embodiments is applied.

FIG. 21 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

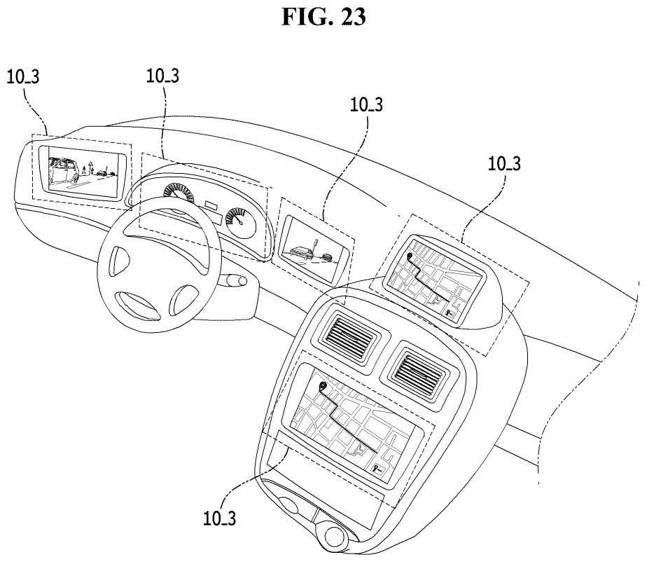

FIG. 22 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

The smart watch 10_2c includes a biometric sensor as an input device, and may provide biometric information recognized by the biometric sensor to the user through the display module. FIG. 23 illustrates a case where an electronic device including a display module is applied to a vehicle. For example, the electronic device 10_4 may be applied to a dashboard, center fascia, etc. of a vehicle, or may be applied to a CID (Center Information Display) placed on a dashboard of a vehicle, or a room mirror display replacing a side mirror.

It will be able to be understood by one of ordinary skill in the art to which the present disclosure belongs that the present disclosure may be implemented in other specific forms without changing the aspects of the present disclosure. Therefore, it is to be understood that the exemplary embodiments described above are illustrative rather than being restrictive in all aspects. It is to be understood that the scope of the present disclosure are defined by the claims, with functional equivalents thereof to be included therein, rather than the detailed description described above, and all modifications and alterations derived from the claims and their equivalents fall within the scope of the present disclosure.

What is claimed is:

1. A display device comprising:
a substrate;
an insulating layer above the substrate, and defining a trench;
a first electrode above the insulating layer and adjacent to the trench in plan view;
a light-providing layer above the first electrode; and
a second electrode above the light-providing layer.

2. The display device of claim 1, further comprising a bank above the insulating layer, wherein the trench is between the first electrode and the bank in plan view.

3. The display device of claim 2, wherein the bank protrudes from the insulating layer along a first direction, and
wherein the trench is recessed from an upper surface of the insulating layer along a direction that is opposite to the first direction.

4. The display device of claim 2, wherein the trench surrounds the first electrode in plan view.

5. The display device of claim 2, wherein the bank surrounds the trench and the first electrode in plan view.

6. The display device of claim 2, wherein the bank comprises:
a first sub-bank above the insulating layer; and
a second sub-bank above the first sub-bank.

7. The display device of claim 6, wherein a width of the first sub-bank is greater than a width of the second sub-bank.

8. The display device of claim 6, wherein the bank further comprises a third sub-bank above the second sub-bank.

9. The display device of claim 8, wherein a width of the second sub-bank is less than a width of the third sub-bank.

10. The display device of claim 8, wherein the second sub-bank has a width that gradually increases along a direction from the first sub-bank toward the third sub-bank.

11. The display device of claim 2, wherein a thickness of the insulating layer in an area overlapping the bank is greater than a thickness of the insulating layer in an area overlapping the trench, and is less than a thickness of the insulating layer in an area overlapping the first electrode.

12. The display device of claim 2, wherein a thickness of the insulating layer in an area overlapping the first electrode is greater than a thickness of the insulating layer in an area overlapping the trench, and is less than a thickness of the insulating layer in an area overlapping the bank.

13. The display device of claim 2, wherein a thickness of the insulating layer in an area overlapping the first electrode is greater than a thickness of the insulating layer in an area overlapping the trench, and is substantially equal to a thickness of the insulating layer in an area overlapping the bank.

14. The display device of claim 2, further comprising a pixel-defining layer between the first electrode and the light-providing layer.

15. The display device of claim 14, wherein edges of the pixel-defining layer surround the first electrode in plan view.

16. The display device of claim 14, wherein the trench surrounds the pixel-defining layer and the first electrode in plan view.

17. The display device of claim 2, wherein at least a portion of the light-providing layer is above the bank and in the trench.

18. The display device of claim 2, wherein a portion of the light-providing layer above the bank, a portion of the light-providing layer in the trench, and a portion of the light-providing layer above the first electrode are separated from each other.

19. The display device of claim 2, wherein a taper angle of the first electrode is less than about 60 degrees.

20. An electronic device comprising a display device comprising:
a substrate;
an insulating layer above the substrate, and defining a trench;
a first electrode above the insulating layer and adjacent to the trench in plan view;
a light-providing layer above the first electrode; and
a second electrode above the light-providing layer.
